(19) United States
(12) Patent Application Publication
(10) Pub. No.: US 2025/0267854 A1
(43) Pub. Date: Aug. 21, 2025

(54) SEMICONDUCTOR DEVICES INCLUDING BIT LINES

(71) Applicant: Samsung Electronics Co., Ltd., Suwon-si (KR)

(72) Inventors: Donghyun KIM, Suwon-si (KR); Chansic YOON, Suwon-si (KR)

(73) Assignee: Samsung Electronics Co., Ltd., Suwon-si (KR)

(21) Appl. No.: 19/018,527

(22) Filed: Jan. 13, 2025

(30) Foreign Application Priority Data
Feb. 15, 2024 (KR) 10-2024-0022000

(51) Int. Cl. H10B 12/00

(52) U.S. Cl. CPC H10B 12/482; H10B 12/02

(57) ABSTRACT

A semiconductor device includes a substrate including a first active area, a bit line on the substrate, crossing the first active area, and extending in a first direction parallel to an upper surface of the substrate, a bit line capping layer extending, in the first direction, on an upper surface of the bit line, and a spacer structure on a sidewall of the bit line and a sidewall of the bit line capping layer, wherein the spacer structure includes an inner spacer on the sidewall of the bit line and a lower side of the sidewall of the bit line capping layer, an upper capping spacer on an upper side of the sidewall of the bit line capping layer, and an outer spacer on a sidewall of the inner spacer and a sidewall of the upper capping spacer.

### CROSS-REFERENCE TO RELATED APPLICATION

This application is based on and claims priority under 35 U.S.C. § 119 to Korean Patent Application No. 10-2024-0022000, filed on Feb. 15, 2024, in the Korean Intellectual Property Office, the disclosure of which is incorporated by reference herein in its entirety.

### BACKGROUND

The inventive concepts relate to semiconductor devices, and more particularly, to semiconductor devices including bit lines.

The size of individual fine circuit patterns for implementing semiconductor devices has been decreased according to the downscaling of the semiconductor devices. In addition, as integrated circuit devices have become highly integrated, bit lines have been decreased in width and gaps therebetween have also been reduced. Therefore, the process difficulty of forming contacts between the bit lines has increased.

### SUMMARY

The inventive concepts provide a semiconductor device capable of decreasing the process difficulty of forming contacts between bit lines.

According to an aspect of the inventive concepts, there is provided a semiconductor device including a substrate including a first active area, a bit line on the substrate, crossing the first active area, and extending in a first direction parallel to an upper surface of the substrate, a bit line capping layer extending, in the first direction, on an upper surface of the bit line, and a spacer structure on a sidewall of the bit line and a sidewall of the bit line capping layer, wherein the spacer structure includes an inner spacer on the sidewall of the bit line and a lower side of the sidewall of the bit line capping layer, an upper capping spacer on an upper side of the sidewall of the bit line capping layer, and an outer spacer on a sidewall of the inner spacer and a sidewall of the upper capping spacer.

According to another aspect of the inventive concepts, there is provided a semiconductor device including a substrate including a first active area, a bit line on the substrate, crossing the first active area, and extending in a first direction parallel to an upper surface of the substrate, a bit line capping layer extending, in the first direction, on an upper surface of the bit line, and a spacer structure on a sidewall of the bit line and a sidewall of the bit line capping layer, wherein the spacer structure includes an inner spacer on the sidewall of the bit line and a lower side of the sidewall of the bit line capping layer and including a first material, an upper capping spacer on an upper side of the sidewall of the bit line capping layer and including a second material that is different from the first material, and an outer spacer on a sidewall of the inner spacer and a sidewall of the upper capping spacer, wherein a bottom surface of the upper capping spacer is at a higher vertical level than the upper surface of the bit line.

According to another aspect of the inventive concepts, there is provided a semiconductor device including a substrate including a plurality of first active areas, a plurality of bit lines on the substrate, crossing the plurality of first active areas, and extending in a first direction parallel to an upper surface of the substrate, a plurality of bit line capping layers respectively extending, in the first direction, on upper surfaces of the plurality of bit lines, a bit line contact between the plurality of first active areas corresponding to a first bit line among the plurality of bit lines and in a bit line contact hole extending into the substrate, a bit line contact spacer filling an inside of the bit line contact hole and contacting a sidewall of the bit line contact, a buried contact between the first bit line and a second bit line, which is adjacent to the first bit line among the plurality of bit lines, and in a buried contact hole extending into the substrate, a spacer structure on a sidewall of the first bit line, wherein the spacer structure includes an inner spacer including a first material and on the sidewall of the first bit line and a lower side of a sidewall of a first bit line capping layer on an upper surface of the first bit line, an upper capping spacer on an upper side of the sidewall of the first bit line capping layer and including a second material that is different from the first material, and an outer spacer on a sidewall of the inner spacer and a sidewall of the upper capping spacer, wherein the semiconductor device further includes a landing pad on the buried contact, and the outer spacer is in contact with a sidewall of the buried contact and a sidewall of the landing pad.

### BRIEF DESCRIPTION OF THE DRAWINGS

Example embodiments of the inventive concepts will be more clearly understood from the following detailed description taken in conjunction with the accompanying drawings in which:

FIG. 1 illustrates a layout of a semiconductor device according to some example embodiments;

FIG. 2 illustrates a layout of a cell array area MCA of FIG. 1;

FIG. 3 is a cross-sectional view of the semiconductor device, taken along a line A-A′ of FIG. 2;

FIG. 4 is a cross-sectional view of the semiconductor device, taken along a line B-B′ of FIG. 2;

FIG. 5 is an enlarged view illustrating a region CX1 of FIG. 3;

FIGS. 6 and 7 are cross-sectional views of a semiconductor device according to some example embodiments;

FIGS. 8 and 9 are cross-sectional views of a semiconductor device according to some example embodiments;

FIGS. 10 and 11 are cross-sectional views of a semiconductor device according to some example embodiments;

FIGS. 12A, 12B, 13A, 13B, and 14 to 27 are cross-sectional views illustrating a method of manufacturing a semiconductor device, according to some example embodiments; and

FIGS. 28 to 37 are cross-sectional views illustrating a method of manufacturing a semiconductor device, according to some example embodiments.

### DETAILED DESCRIPTION

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, one or more example embodiments of the inventive concepts will be described in detail with reference to the attached drawings.

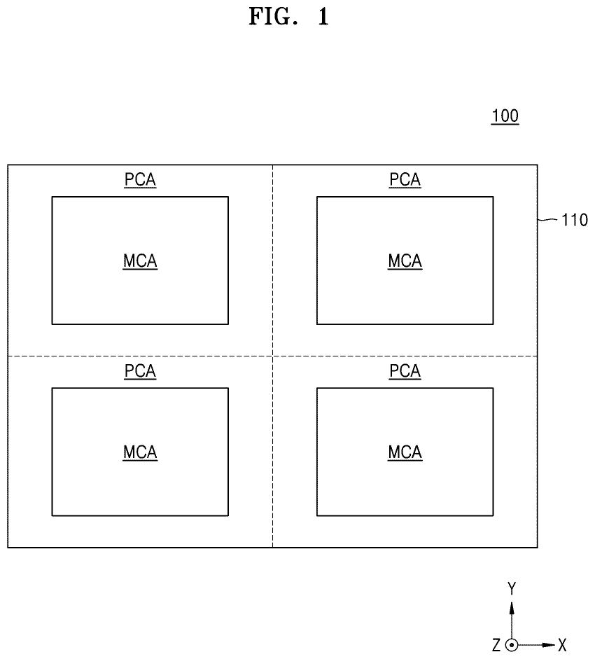

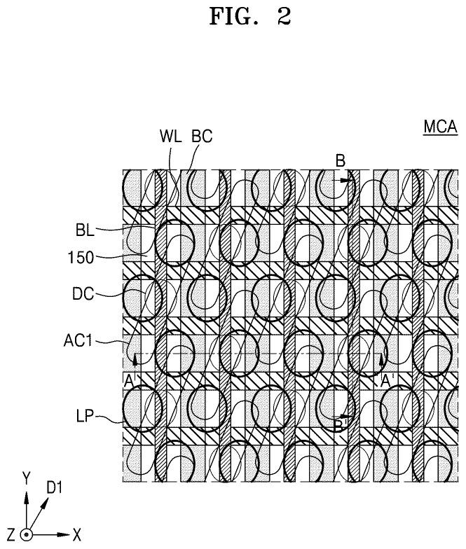

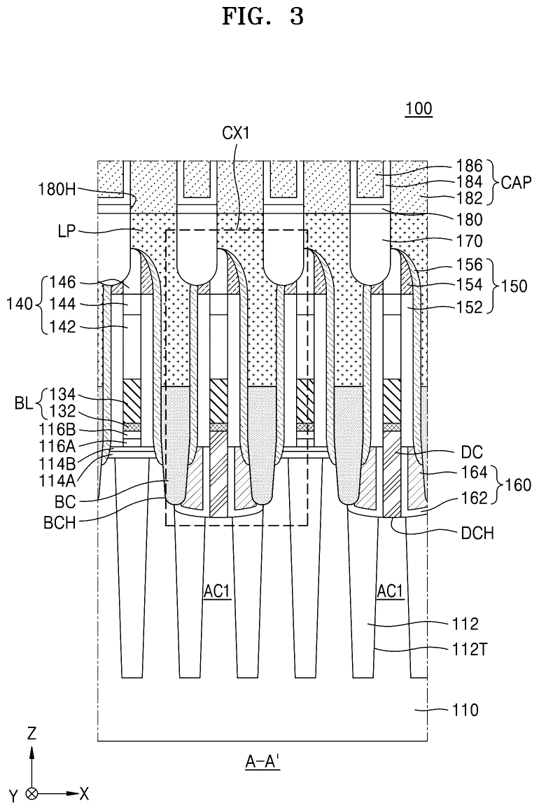

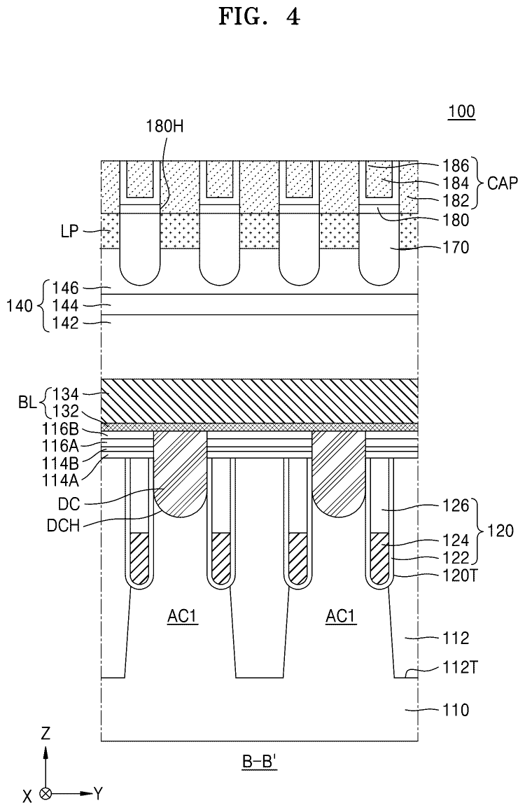

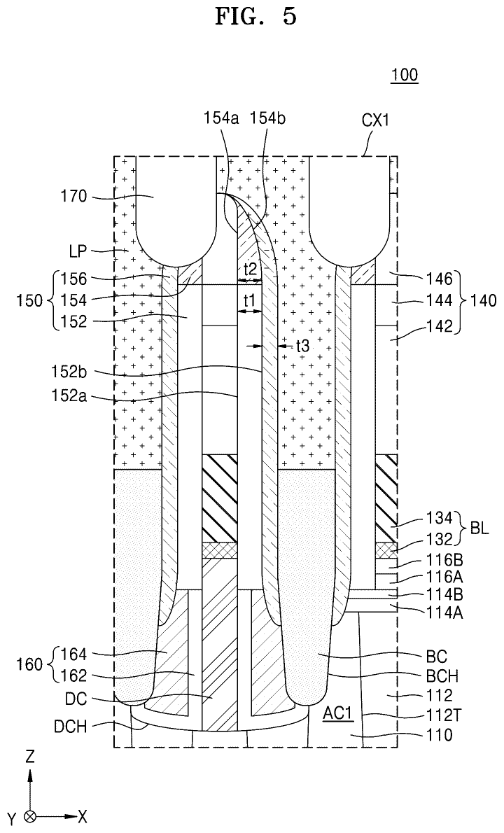

FIG. 1 illustrates a layout of a semiconductor device 100 according to some example embodiments. FIG. 2 illustrates a layout of a cell array area MCA of FIG. 1. FIG. 3 is a cross-sectional view of the semiconductor device 100, taken along a line A-A′ of FIG. 2. FIG. 4 is a cross-sectional view of the semiconductor device 100, taken along a line B-B′ of FIG. 2. FIG. 5 is an enlarged view illustrating a region CX1 of FIG. 3.

Referring to FIGS. 1 to 5, the semiconductor device 100 may include a substrate 110 including a cell array area MCA and a peripheral circuit area PCA. The cell array area MCA may be a memory cell area of a dynamic random access memory (DRAM) device, and the peripheral circuit area PCA may be a core area or a peripheral circuit area of the DRAM device. For example, the cell array area MCA may include a cell transistor and a capacitor structure CAP connected thereto, and the peripheral circuit area PCA may include a peripheral circuit transistor configured to transmit signals and/or power to the cell transistor included in the cell array area MCA. In some example embodiments, the peripheral circuit transistor may configure various circuits, such as a command decoder, a control logic, an address buffer, a row decoder, a column decoder, a sense amplifier, and a data input/output circuit.

Device isolation trenches 112T may be formed in the substrate 110, and first device isolation layers 112 may be formed in the device isolation trenches 112T. A plurality of first active areas AC1 may be defined in the cell array area MCA of the substrate 110 by the first device isolation layer 112.

As illustrated in FIG. 2, in the cell array area MCA, the first active areas AC1 may be arranged to have long axes in a first diagonal direction D1 that is inclined with respect to a first horizontal direction X and a second horizontal direction Y. Word lines WL may extend in parallel with each other in the first horizontal direction X by crossing the first active areas AC1. On the word lines WL, the bit lines BL may extend in parallel with each other in the second horizontal direction Y. The bit lines BL may be connected to the first active areas AC1 through bit line contacts DC, respectively.

Buried contacts BC may be formed between two bit lines BL, which are adjacent to each other from among the bit lines BL. Landing pads LP may be formed on the buried contacts BC. The buried contacts BC and the landing pads LP may function as connectors for connecting a lower electrode 182 of the capacitor structure CAP, which is formed on the bit lines BL, to the first active area AC1. The landing pads LP may be arranged to partially overlap the buried contacts BC and the bit lines BL, respectively.

A substrate 110 may include silicon such as single crystalline silicon, polycrystalline silicon, or amorphous silicon. In other example embodiments, the substrate 110 may include at least one selected from among germanium (Ge), silicon-germanium (SiGe), silicon carbide (SiC), gallium arsenide (GaAs), indium arsenide (InAs), and/or indium phosphide (InP). In some example embodiments, the substrate 110 may include a conductive area, for example, a well doped with impurities or a structure doped with impurities.

The first device isolation layer 112 may include an oxide film, a nitride film, or a combination thereof. A first buffer insulating layer 114A and a second buffer insulating layer 114B may be sequentially arranged on the upper surface of the substrate 110. The first buffer insulating layer 114A and the second buffer insulating layer 114B may each include silicon oxide (SiO), silicon oxynitride (SiON), or silicon nitride (SiN).

A plurality of word line trenches 120T extending in the first horizontal direction X may be arranged on the substrate 110, and a buried gate structure 120 may be arranged in the word line trenches 120T. The buried gate structure 120 may include a gate dielectric layer 122, a gate electrode 124, and a word line capping layer 126 which are arranged in each word line trench 120T. The gate electrodes 124 may respectively correspond to the word lines WL illustrated in FIG. 2.

The gate dielectric layers 122 may each include a silicon oxide film, a silicon nitride film, a silicon oxynitride film, an oxide/nitride/oxide (ONO) film, or a high-k dielectric film having a greater dielectric constant than the silicon oxide film. The gate electrodes 124 may each include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. A plurality of word line capping layers 126 may each include a silicon oxide layer, a silicon nitride layer, a silicon oxynitride layer, or a combination thereof.

A plurality of bit line contact holes DCH may extend into the substrate 110 by penetrating the first buffer insulating layer 114A and the second buffer insulating layer 114B, and the bit line contacts DC may be formed in the bit line contact holes DCH. The bit line contacts DC may be respectively connected to the first active areas AC1. The bit line contacts DC may each include Si, Ge, W, WN, cobalt (Co), nickel (Ni), aluminum (Al), molybdenum (Mo), ruthenium (Ru), Ti, TiN, Ta, TaN, copper (Cu), or a combination thereof.

The bit lines BL may extend, in the second horizontal direction Y, on the substrate 110 and the bit line contacts DC. The bit lines BL may be respectively connected to the first active areas A1 through the bit line contacts DC.

In some example embodiments, the first buffer insulating layer 114A and the second buffer insulating layer 114B may be sequentially arranged on the substrate 110, a first buffer insulating line 116A and a second buffer insulating line 116B may be sequentially arranged on the second buffer insulating layer 114B, and the bit lines BL may be arranged on the first buffer insulating line 116A and the second buffer insulating line 116B. For example, the first buffer insulating line 116A and the second buffer insulating line 116B may be patterned together through a process of patterning the bit lines BL, and as illustrated in FIG. 3, both sidewalls of the first buffer insulating line 116A and both sidewalls of the second buffer insulating line 116B may be aligned with both sidewalls of the bit lines BL, respectively. In some example embodiments, however, the first buffer insulating line 116A and the second buffer insulating line 116B may be omitted, and in this case, the bit lines BL may be directly arranged on the second buffer insulating layer 114B.

In some example embodiments, each bit line BL may include a lower conductive layer 132 and an upper conductive layer 134.

The lower conductive layer 132 may extend on the second buffer insulating line 116B in the second horizontal direction Y. The lower conductive layer 132 may be arranged on the upper surface of the bit line contact DC. The lower conductive layer 132 may include at least one of Si, Ge, W, WN, Co, Ni, Al, Mo, Ru, Ti, TiN, Ta, TaN, Cu, cobalt silicide, nickel silicide, and/or tungsten silicide.

The upper conductive layer 134 may be arranged on the upper surface of the lower conductive layer 132 and extend in the second horizontal direction Y. In some example embodiments, the upper conductive layer 134 may include any one of W, Ru, Mo, Ti, rhodium (Ro), iridium (Ir), and/or an alloy thereof.

A plurality of bit line capping layers 140 may be arranged on the bit lines BL, respectively. Each bit line capping layer 140 may include a first capping layer 142, a second capping layer 144, and a third capping layer 146 which are sequentially arranged on the upper surface of the bit line BL. The first capping layer 142, the second capping layer 144, and the third capping layer 146 may include at least one of SiN, SiO, and/or SiON.

Spacer structures 150 may be arranged on the sidewalls of each bit line BL and the sidewalls of each bit line capping layer 140. The spacer structure 150 may include an inner spacer 152, an upper capping spacer 154, and an outer spacer 156.

The inner spacer 152 may be arranged on the sidewall of the bit line BL and the lower side of the sidewall of the bit line capping layer 140 and may extend in the second horizontal direction Y. In some example embodiments, the upper surface of the inner spacer 152 may be arranged at a higher level than the upper surface of the bit line BL and have a flat profile. In some example embodiments, the upper surface of the inner spacer 152 may have a flat profile resulting from an etch-back process or an etching process applied to the inner spacer 152. The inner spacer 152 may include a first sidewall 152a, which faces or contacts the bit line BL and the bit line capping layer 140, and a second sidewall 152b, which is opposite to the first sidewall 152a. Each of the first sidewall 152a and the second sidewall 152b may have a substantially flat profile.

In some example embodiments, as illustrated in FIG. 5, the inner spacer 152 may be arranged on the sidewalls of the first buffer insulating line 116A and the second buffer insulating line 116B, and the upper surface of the inner spacer 152 may contact the upper surface of the second buffer insulating layer 114B. In addition, the inner spacer 152 may be arranged on the upper side of the sidewall of the bit line contact DC.

In some example embodiments, the inner spacer 152 may have a first width t1 in the first horizontal direction X, and for example, the first width t1 may be in a range from about 1 nm to about 20 nm. In some example embodiments, the inner spacer 152 may include a first material, and the first material may include SiO.

The upper capping spacer 154 may be arranged on the upper side of the sidewall of the bit line capping layer 140 and the upper surface of the inner spacer 152. The bottom surface of the upper capping spacer 154 may have a flat profile and contact the upper surface of the inner spacer 152. The upper capping spacer 154 may be arranged to vertically overlap the inner spacer 152 and may extend in the second horizontal direction Y. The upper capping spacer 154 may include a first sidewall 154a facing or contacting the bit line capping layer 140 and a second sidewall 154b opposite to the first sidewall 154a.

In some example embodiments, the bottom surface of the upper capping spacer 154 may have a second width t2 in the first horizontal direction X, and the second width t2 may be substantially the same as the first width t1. In some example embodiments, the second width t2 may be greater than the first width t1. For example, the second width t2 may be in a range from about 1 nm to about 20 nm. The upper capping spacer 154 may have a tapered shape with the width narrowing upwards. For example, the upper side of the upper capping spacer 154, which is adjacent to the uppermost surface of the bit line capping layer 140, may have a width that is less than the second width t2 of the bottom surface of the upper capping spacer 154.

In some example embodiments, as the bottom surface of the upper capping spacer 154 has the second width t2 in the first horizontal direction X and the second width t2 is substantially the same as the first width t1 of the inner spacer 152, the second sidewall 154b of the upper capping spacer 154 (e.g., the second sidewall 154b that is opposite to the first sidewall 154a of the upper capping spacer 154 facing the bit line capping layer 140) may be aligned (e.g., coplanar) with and continuously connected to the second sidewall 152b of the inner spacer 152 (e.g., the second sidewall 152b that is opposite to the first sidewall 152a of the inner spacer 152 facing the bit line capping layer 140).

In some example embodiments, the upper capping spacer 154 may include a second material, and the second material may be different from the first material and have an etch selectivity with respect to the first material. The second material may include at least one of SiN, SiON, silicon oxycarbide (SiOC), silicon oxycarbonitride (SiOCN), or titanium nitride (TiN).

In some example embodiments, the bottom surface of the upper capping spacer 154 may be at a higher level than the upper surface of the bit line BL. FIG. 3 illustrates that the bottom surface of the upper capping spacer 154 is at substantially the same level as the bottom surface of the third capping layer 146 of the bit line capping layer 140, but in some example embodiments, the bottom surface of the upper capping spacer 154 may be at a lower level than the upper surface of the third capping layer 146 or at a higher level than the bottom surface of the third capping layer 146. In some example embodiments, the bottom surface of the upper capping spacer 154 may be at a lower level than the upper surface of the second capping layer 144 or at a higher level than the bottom surface of the second capping layer 144. In some example embodiments, the bottom surface of the upper capping spacer 154 may be at a lower level than the upper surface of the first capping layer 142 or at a higher level than the bottom surface of the first capping layer 142.

The outer spacer 156 may be arranged on the second sidewall 152b of the inner spacer 152 and the second sidewall 154b of the upper capping spacer 154. For example, the inner spacer 152 may be arranged between the outer spacer 156 and the bit line BL and between the outer spacer 156 and the lower side of the bit line capping layer 140, and the upper capping spacer 154 may be arranged between the outer spacer 156 and the upper side of the bit line capping layer 140.

In some example embodiments, the outer spacer 156 may include a material with an etch selectivity with respect to the inner spacer 152, for example, SiN. In some example embodiments, the outer spacer 156 may have a third width t3 in the first horizontal direction X, and the third width t3 may be less than the first width t1 of the inner spacer 152. For example, the third width t3 may be in a range from about 0.5 nm to about 10 nm.

In some example embodiments, as the third width t3 of the outer spacer 156 is less than the first width t1 of the inner spacer 152, the parasitic capacitance by the spacer structure 150 may be reduced. In addition, as the upper capping spacer 154 is arranged on the upper surface of the inner spacer 152, the exposure of the inner spacer 152 to the etching atmosphere or damage to the inner spacer 152 may be prevented or reduced in likelihood, wherein such exposure or damage may occur during the formation of buried contact holes BCH and/or the etching of the buried contacts BC.

The bit line contact spacer 160 may be arranged inside the bit line contact hole DCH and may cover or contact the sidewall of the bit line contact DC. The bit line contact spacer 160 may include an insulating liner 162 and a buried spacer 164. The insulating liner 162 may contact the sidewall of the bit line contact DC and may be conformally arranged inside the bit line contact hole DCH. The buried spacer 164 may fill the inside of the bit line contact hole DCH on the insulating liner 162. In some example embodiments, the insulating liner 162 may include SiO, and the buried spacer 164 may include SiN.

In some example embodiments, the upper surface of the bit line contact spacer 160 may have a flat profile, and the bottom surface of the inner spacer 152 may be arranged on the upper surface of the bit line contact spacer 160. In addition, the bottom surface of the outer spacer 156 may be at a lower level than the bottom surface of the inner spacer 152, and the lower side of the outer spacer 156 may contact the sidewall of the bit line contact spacer 160.

A plurality of buried contacts BC may be arranged between bit lines BL, respectively. For example, the upper side of each buried contact BC may be arranged between two adjacent spacer structures 150 and be in contact therewith. For example, the upper side of each buried contact BC may be surrounded by the outer spacer 156. The lower side of each buried contact BC may be arranged inside the buried contact hole BCH that extends into the substrate 110 by penetrating the bit line contact spacer 160. The lower side of each buried contact BC may contact the bit line contact spacer 160, for example, the buried spacer 164 and the insulating liner 162. The bottom portion and the lower side of the sidewall of each buried contact BC may contact the first active area AC1. In some example embodiments, the buried contacts BC may include polysilicon.

A plurality of insulating fences (not shown) may be arranged between two adjacent bit lines BL in the second horizontal direction Y. The insulating fences may vertically overlap the word line trenches 120T. In a plan view, the buried contacts BC and the insulating fences may be alternately arranged between two bit lines BL extending in the second horizontal direction Y.

The landing pads LP may be arranged on the buried contacts BC. The landing pads LP may each include a conductive barrier layer (not shown) and a landing pad conductive layer (not shown). The conductive barrier layer may include Ti, TiN, or a combination thereof. The landing pad conductive layer may include a metal, metal nitride, conductive polysilicon, or a combination thereof. For example, the landing pad conductive layer may include W. In the plan view, the land pads LP may have island patterns. The landing pads LP may contact the outer spacer 156 and at least a portion of the upper capping spacer 154 and may not contact the inner spacer 152.

The landing pads LP may be electrically insulated from each other by insulating patterns 170 surrounding the periphery of the landing pads LP. The insulating pattern 170 may include at least one of SiN, SiO, and/or SiON.

An etch stop layer 180 may be arranged on the insulating pattern 170 and may include an opening 180H. The opening 180H may be at a location corresponding to the landing pad LP, and the upper surface of the landing pad LP may be at the bottom of the opening 180H.

The capacitor structure CAP may be arranged on the etch stop layer 180. The capacitor structure CAP may include a lower electrode 182, a capacitor dielectric layer 184, and an upper electrode 186. The bottom portion of the lower electrode 182 is arranged inside the opening 180H of the etch stop layer 180 so that the bottom portion may be on the landing pad LP. The capacitor dielectric layer 184 may have a small thickness to conformally cover the lower electrode 182, and the upper electrode 186 may be arranged on the capacitor dielectric layer 184.

In general, as widths of the bit lines and gaps therebetween decrease, the difficulty of forming the buried contacts increases. In addition, it is required to produce a bit line spacer with a material having a relatively low dielectric constant to reduce parasitic capacitance, and a relatively thin structure, in which an inner spacer includes SiO and an outer spacer includes SiN, has been suggested. However, during the process of etching the buried contact holes or polysilicon used to form the buried contacts BC, the outer spacer may be damaged or removed, and accordingly, the inner spacer may also be damaged or removed.

According to the one or more example embodiments, however, the inner spacer 152 including SiO may be formed on both sidewalls of the bit lines BL, and after an upper portion of the inner spacer 152 is partially removed, the upper capping spacer 154 including, for example, SiN may be formed in the region formed by the removal of the upper portion of the inner spacer 152. Therefore, during the etching process for forming the buried contact holes BCH or the process of forming the buried contacts BC, the upper capping spacer 154 may function as a mask, and thus, the inner spacer 152 may be prevented or reduced in likelihood from being exposed or damaged. Therefore, the semiconductor device 100 may have reduced parasitic capacitance, and thus, the electrical characteristics of the semiconductor device 100 may be improved.

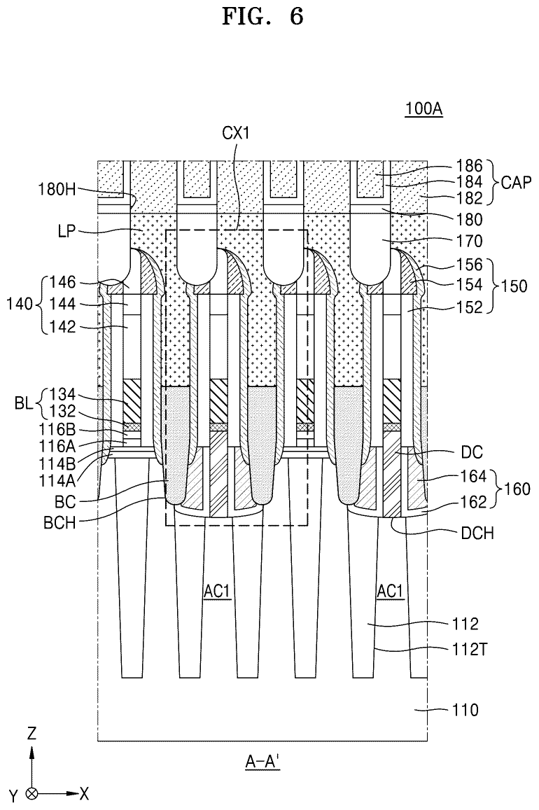

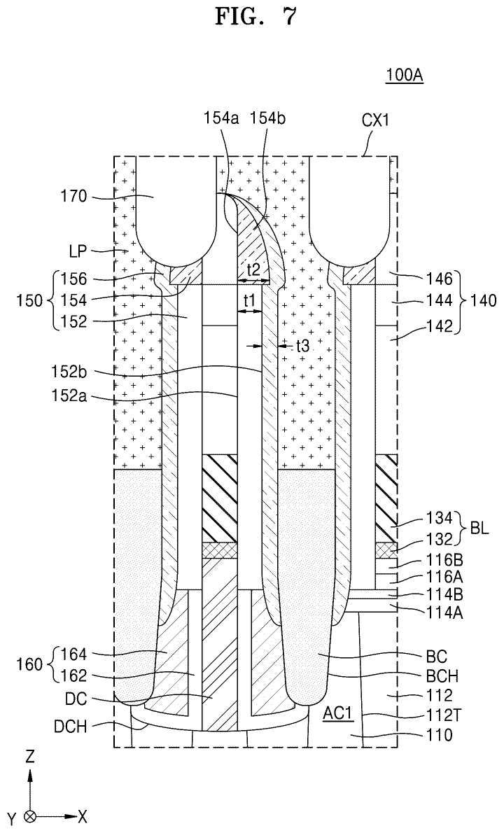

FIGS. 6 and 7 are cross-sectional views of a semiconductor device 100A according to some example embodiments.

Referring to FIGS. 6 and 7, the bottom surface of the upper capping spacer 154 may have the second width t2 in the first horizontal direction X, and the second width t2 may be greater than the first width t1 of the inner spacer 152. As illustrated in FIGS. 6 and 7, because the second width t2 of the upper capping spacer 154 is greater than the first width t1 of the inner spacer 152, the second sidewall 154b of the upper capping spacer 154 may protrude outwards with respect to the second sidewall 152b of the inner spacer 152.

In some example embodiments, the upper surface of the inner spacer 152 may have a flat profile, and the bottom surface of the upper capping spacer 154 may contact the upper surface of the inner spacer 152 and have a flat profile.

In some example embodiments, the outer spacer 156 may be conformally arranged at the boundary of the second sidewall 154b of the upper capping spacer 154 and the second sidewall 152b of the inner spacer 152, and a portion of the outer spacer 156 on the upper side of the second sidewall 154b of the upper capping spacer 154 may be tapered upwards (e.g., the width of the outer spacer 156 narrowing upwards).

According to some example embodiments, as the upper capping spacer 154 has a greater width than the inner spacer 152 on the inner spacer 152, the upper capping spacer 154 may function as a mask during the etching process for forming the buried contact holes BCH or the process of forming the buried contacts BC, thereby preventing or reducing in likelihood the exposure or damage to the inner spacer 152. Therefore, the semiconductor device 100A may have reduced parasitic capacitance,

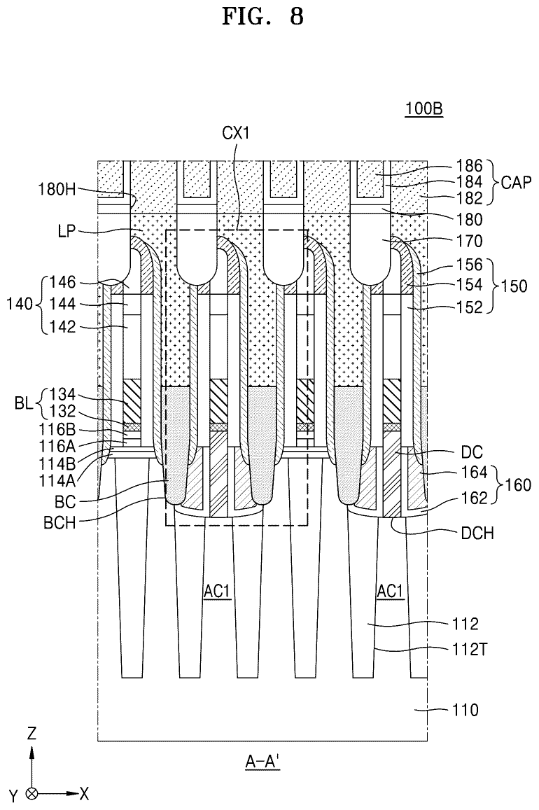

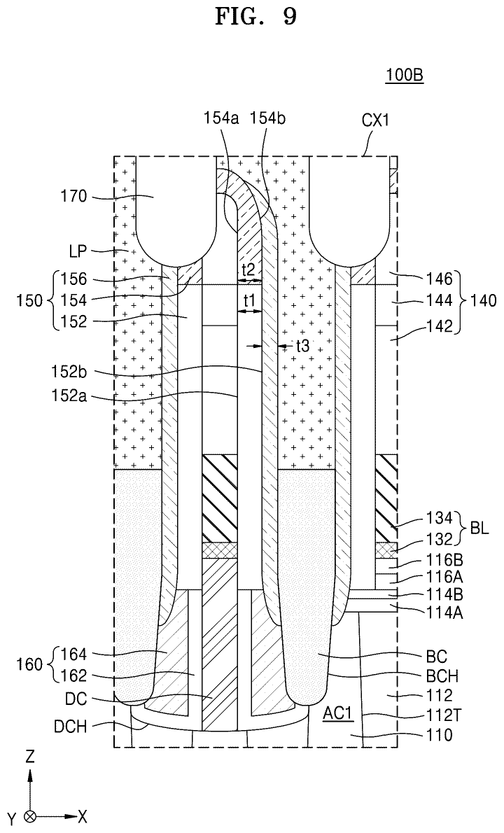

FIGS. 8 and 9 are cross-sectional views of a semiconductor device 100B according to some example embodiments.

Referring to FIGS. 8 and 9, the upper capping spacer 154 may cover the uppermost surface of a third capping layer 146, and the thickness of the upper capping spacer 154 arranged on the uppermost surface of the third capping layer 146 may be the same as or similar to the second width t2 of the bottom surface of the upper capping spacer 154.

According to some example embodiments, as the upper capping spacer 154 has a thickness that is great enough to fully cover the uppermost surface of the third capping layer 146 on the inner spacer 152, the upper capping spacer 154 may function as a mask during the etching process for forming the buried contact holes BCH or the process of forming the buried contacts BC, and the inner spacer 152 may be prevented or reduced in likelihood from being exposed or damaged. Therefore, the semiconductor device 100B may have reduced parasitic capacitance, and thus, the electrical characteristics of the semiconductor device 100B may be improved.

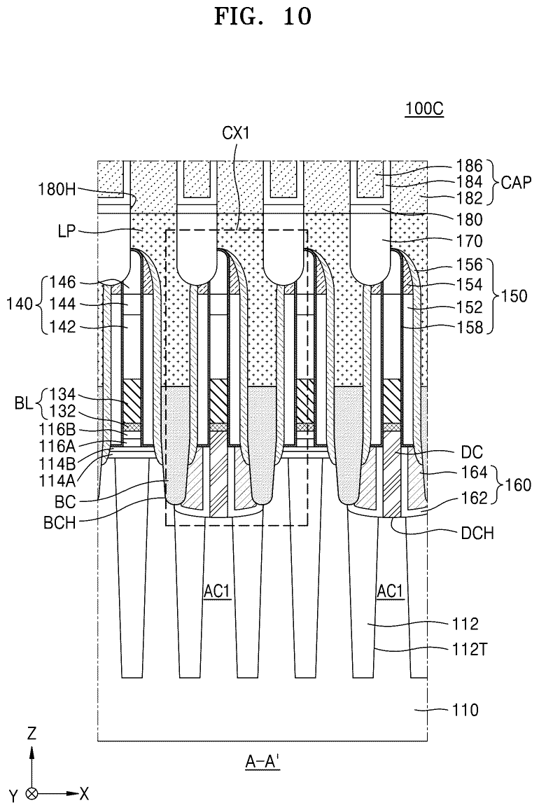

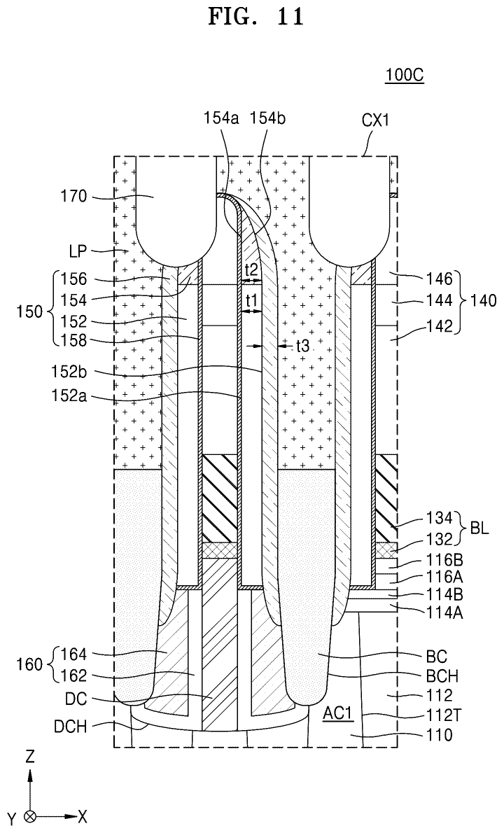

FIGS. 10 and 11 are cross-sectional views of a semiconductor device 100C according to some example embodiments.

Referring to FIGS. 10 and 11, the spacer structure 150 may further include a liner 158. The liner 158 may be arranged between the bit line capping layer 140 and the upper capping spacer 154 and between the bit line capping layer 140 and the inner spacer 152. In some example embodiments, the liner 158 may extend between the bottom surface of the inner spacer 152 and the upper surface of the bit line contact spacer 160. The liner 158 may include SiN. In some example embodiments, the liner 158 may have a thickness ranging from about 0.5 nm to about 2 nm.

In some example embodiments, the liner 158 may extend to the sidewall of the bit line contact DC. In some example embodiments, unlike the illustrations of FIGS. 10 and 11, the liner 158 may be arranged on the inner wall of the bit line contact hole DCH, for example, between the substrate 110 and the bit line contact spacer 160 on the inner wall of the bit line contact hole DCH.

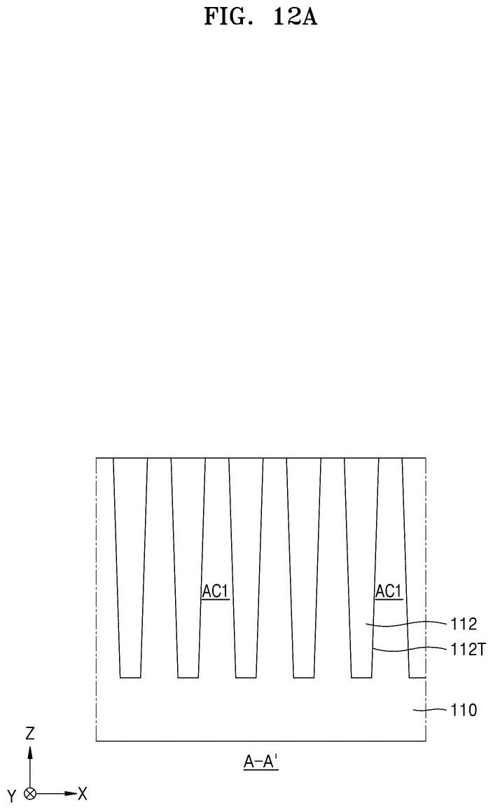

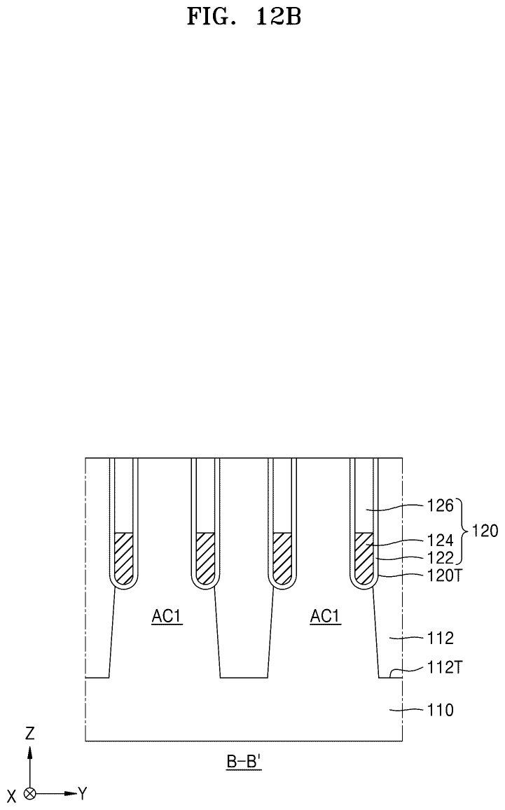

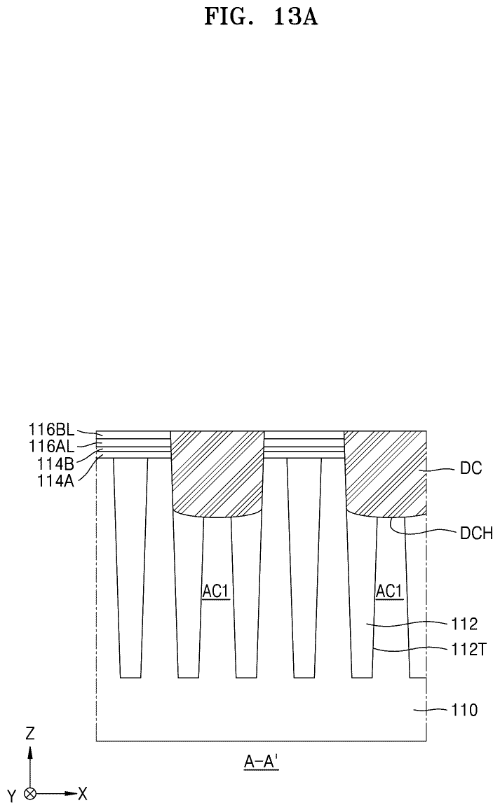

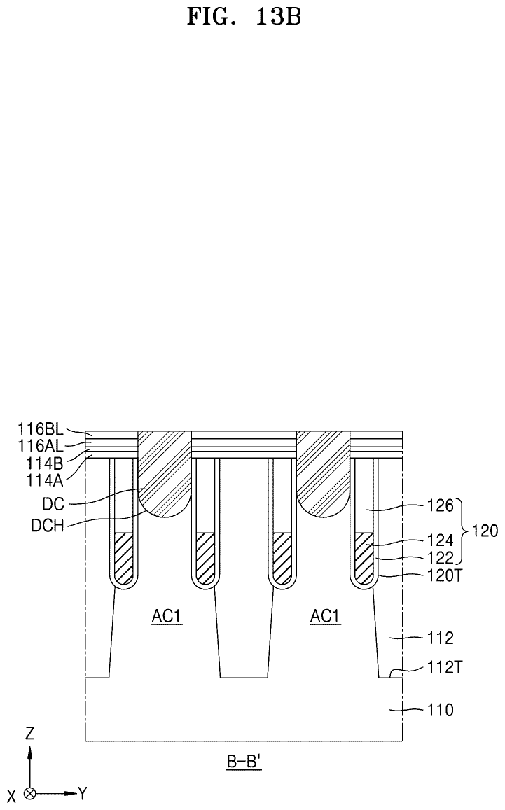

FIGS. 12A, 12B, 13A, 13B, and 14 to 27 are cross-sectional views illustrating a method of manufacturing the semiconductor device 100, according to some example embodiments. In detail, FIGS. 12A, 13A, and 14 to 27 are cross-sectional views corresponding to the cross-section A-A′ of the semiconductor device 100 of FIG. 2, and FIGS. 12B and 13B are cross-sectional views corresponding to the cross-section B-B′ of the semiconductor device 100 of FIG. 2.

Referring to FIGS. 12A and 12B, the device isolation trenches 112T may be formed on the substrate 110.

Then, the first device isolation layer 112 filling the device isolation trenches 112T may be formed. A plurality of first active areas AC1 may be defined on the substrate 110 by the first device isolation layer 112. In a plan view, the first active areas AC1 may extend in a first diagonal direction D1 (see FIG. 2) that is inclined at a certain angle with respect to the first horizontal direction X and the second horizontal direction Y.

In some example embodiments, the device isolation layer 112 may include SiO, SiN, SiON, or a combination thereof. In some example embodiments, the first device isolation layer 112 may have a double-layer structure including a silicon oxide layer and a silicon nitride layer, but the example embodiments are not limited thereto.

A mask pattern (not shown) may be formed on the substrate 110 and used as an etch mask to remove a portion of the substrate 110, thereby forming the word line trenches 120T. For example, the mask pattern for forming the word line trenches 120T may be formed according to double patterning technology (DPT) or quadruple patterning technology (QPT), but one or more example embodiments are not limited thereto.

Then, the gate dielectric layer 122, the gate electrode 124, and the word line capping layer 126 may be sequentially formed in the word line trench 120T.

For example, the gate dielectric layer 122 may be conformally arranged on the inner wall of the word line trench 120T. The gate electrode 124 may be formed by filling the word line trench 120T with a conductive layer (not illustrated), etching-back an upper portion of the conductive layer, and then exposing an upper portion of the word line trench 120T again.

Referring to FIGS. 13A and 13B, the first buffer insulating layer 114A and the second buffer insulating layer 114B may be formed in the first active area AC1 and the first device isolation layer 112. Then, a first buffer insulating line layer 116AL and a second buffer insulating line layer 116BL may be formed on the first buffer insulating layer 114A and the second buffer insulating layer 114B.

In some example embodiments, the first buffer insulating layer 114A may be formed using SiO, and the second buffer insulating layer 114B may be formed using SiN. The first buffer insulating line layer 116AL may be formed using SiO, and the second buffer insulating line layer 116BL may be formed using SiN. However, the inventive concepts are not limited thereto.

Then, the bit line contact hole DCH may be formed by partially removing the first buffer insulating line layer 116AL, the second buffer insulating line layer 116BL, the first buffer insulating layer 114A, the second buffer insulating layer 114B, and the substrate 110. Next, the bit line contact DC may be formed in the bit line contact hole DCH by using a conductive material.

In some example embodiments, the bit line contact DC may be formed using Si, Ge, W, WN, Co, Ni, Al, Mo, Ru, Ti, TiN, Ta, TaN, Cu, or a combination thereof. In some example embodiments, the bit line contact DC may be formed using Si, Ge, W, WN, Co, Ni, Al, Mo, Ru, Ti, TiN, TiSiN, Ta, TaN, Cu, or a combination thereof.

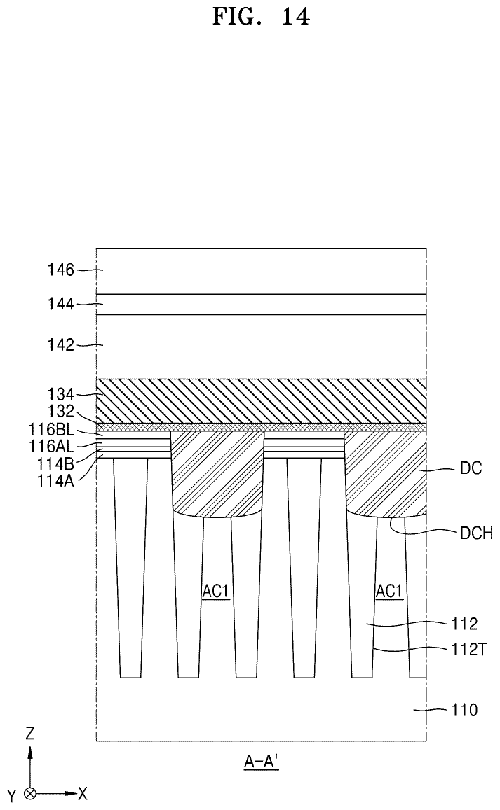

Referring to FIG. 14, the lower conductive layer 132 may be formed on the bit line contact DC and the second buffer insulating line layer 116BL. Then, the upper conductive layer 134 may be formed on the lower conductive layer 132.

In some example embodiments, the lower conductive layer 132 may be formed using at least one of Si, Ge, W, WN, Co, Ni, Al, Mo, Ru, Ti, TiN, Ta, TaN, or Cu, cobalt silicide, nickel silicide, and/or tungsten silicide. In some example embodiments, the upper conductive layer 134 may include any one of W, Ru, Mo, Ti, Ro, Ir, and/or an alloy thereof.

In some example embodiments, the lower conductive layer 132 and the upper conductive layer 134 may be formed through at least one of physical vapor deposition (PVD), chemical vapor deposition (CVD), and/or atomic layer deposition (ALD).

Then, a bit line capping layer stack may be formed on the upper conductive layer 134. The bit line capping layer stack may include a first capping layer 142, a second capping layer 144, and a third capping layer 146 which are sequentially arranged on the upper surface of the upper conductive layer 134. The first capping layer 142, the second capping layer 144, and the third capping layer 146 may each be formed using at least one of SiN, SiO, and/or SiON.

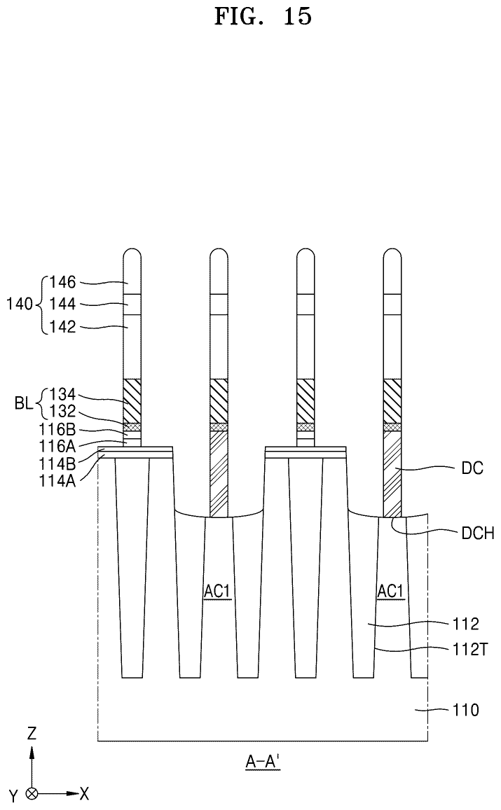

Referring to FIG. 15, the mask pattern (not shown) may be formed on the bit line capping layer stack, and the bit line capping layer stack may be patterned, thus forming the bit line capping layer 140. The upper conductive layer 134 and the lower conductive layer 132 may be patterned by using the bit line capping layer 140 as the etch mask, and the bit lines BL may be formed.

During the patterning process for forming the bit lines BL, a portion of the bit line contact DC arranged in the bit line contact hole DCH may be removed together. Accordingly, as illustrated in FIG. 15, the sidewall of the bit line contact DC may be aligned with the sidewall of the bit line BL, and the inner wall of the bit line contact hole DCH (e.g., the surface of the substrate 110) may be exposed to both sides of the bit line contact DC.

During the patterning process for forming the bit lines BL, a portion of the first buffer insulating line layer 116AL and a portion of the second buffer insulating line layer 116BL are removed together, and thus, the first buffer insulating line 116A and the second buffer insulating line 116B arranged under the bit lines BL may remain.

Selectively, a cleaning process may be performed after the patterning process of the bit line BL. The cleaning process may be performed to remove etching residues of the patterning process and may be conducted, for example, by a rinsing process using a wet cleaning solution.

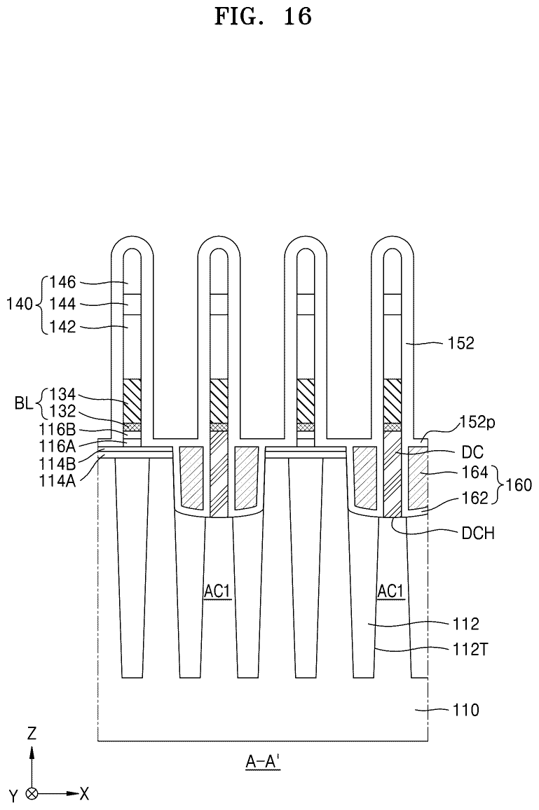

Referring to FIG. 16, the inner spacer 152 may be formed on the bit line BL, the bit line capping layer 140, and the sidewall of the bit line contact DC, and the insulating liner 162 and the buried spacer 164 may be sequentially formed on the inner wall of the bit line contact hole DCH, thereby forming the bit line contact spacer 160.

In some example embodiments, the inner spacer 152 may include a first material, and the first material may include SiO. In some example embodiments, the insulating liner 162 may include a first material, and the first material may include SiO.

In some example embodiments, the process of forming the insulating liner 162 may be performed in the same process as the process of forming a portion of the inner spacer 152. For example, a first portion of the inner spacer 152 (a portion of the inner spacer 152 having a first thickness that is less than the total thickness of the inner spacer 152) may be formed on the bit line BL and the sidewall of the bit line capping layer 140, and the insulating liner 162 may be formed on the inner wall of the bit line contact hole DCH. Then, the buried spacer 164 may fill the inside of the bit line contact hole DCH and the insulating liner 162. The buried spacer 164 may be arranged on the upper surface of the insulating liner 162 inside the bit line contact hole DCH, and the etch-back process or recess process may be performed on the upper side of the buried spacer 164 until the upper surface of the buried spacer 164 is at the same level as the upper surface of the second buffer insulating layer 114B. Then, a second portion of the inner spacer 152 (a portion of the inner spacer 152 having a second thickness that is less than the total thickness of the inner spacer 152) may be formed on the bit line BL and the sidewall of the bit line capping layer 140, and the second portion of the inner spacer 152 may cover the upper surface of the buried spacer 164. A portion of the inner spacer 152 that is on the upper surface of the buried spacer 164 may be referred to as a horizontal extension 152p.

In other example embodiments, the process of forming the insulating liner 162 may be formed in a different process from the process of forming a portion of the inner spacer 152. For example, the insulating liner 162 may be formed first on the inner wall of the bit line contact hole DCH, and the buried spacer 164 may fill the insulating liner 162 and the inside of the bit line contact hole DCH. The inner spacer 152 may be formed on the bit line BL, the bit line capping layer 140, the sidewall of the bit line contact DC, and the upper surface of the buried spacer 164.

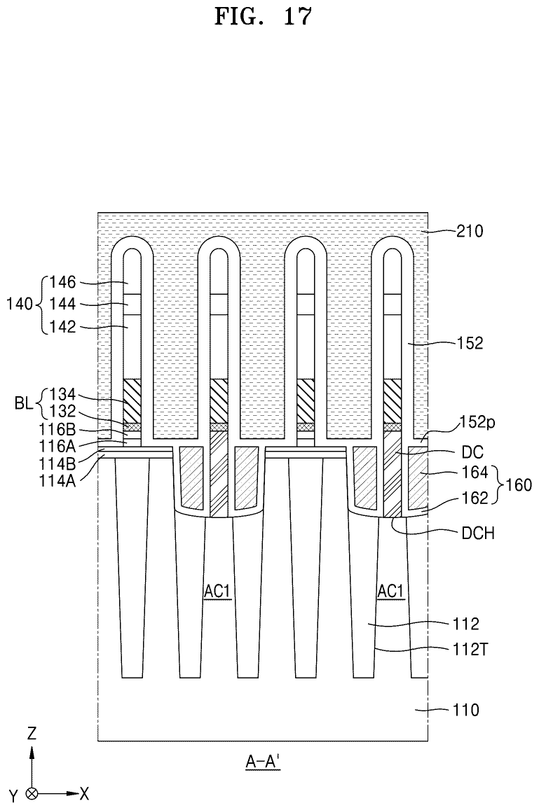

Referring to FIG. 17, a protective layer 210 may be formed on the inner spacer 152. The protective layer 210 may be formed using at least one of a spin-on hard mask, a spin-on dielectric, an amorphous carbon layer, silicon, and silicon carbide. The protective layer 210 may be formed at a height that is sufficient enough to cover the uppermost surface of the inner spacer 152, and the space between adjacent bit lines BL may be completely filled with the protective layer 210.

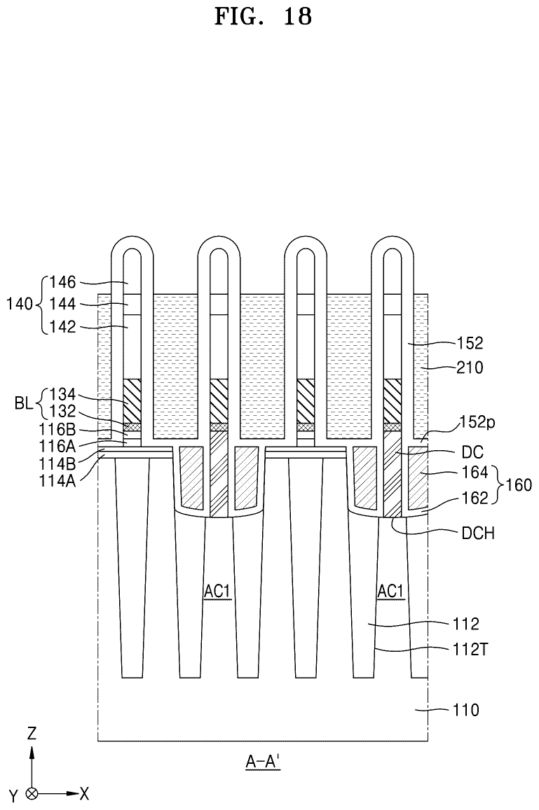

Referring to FIG. 18, the height of the protective layer 210 may be reduced by performing the etch-back process on the upper side of the protective layer 210. Consequently, the upper side of the inner spacer 152 may be exposed.

In example embodiments, the inner spacer 152, which is at a higher level than the reduced level of the upper surface of the protective layer 210, may have a height ranging from about 3 nm to about 100 nm, but one or more example embodiments are not limited thereto. For example, depending on the progress of the etch-back process of the protective layer 210, the exposure degree of the inner spacer 152 may vary.

FIG. 18 illustrates that the protective layer 210 has an upper surface that is at a similar vertical level to the upper surface of the second capping layer 144 or the bottom surface of the third capping layer 146, but the level of the upper surface of the protective layer 210 may vary. In some example embodiments, the upper surface of the protective layer 210 may be at a level that is lower than that of the upper surface of the second capping layer 144 but higher than that of the upper surface of the bit line BL. In some example embodiments, the upper surface of the protective layer 210 may be at a level that is higher than that of the upper surface of the second capping layer 144 and that of the upper surface of the third capping layer 146.

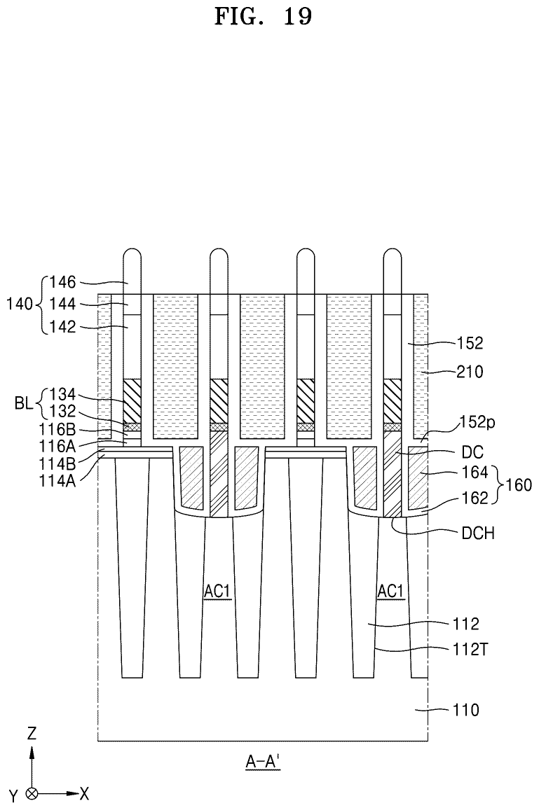

Referring to FIG. 19, a portion of the inner spacer 152 exposed above the upper surface of the protective layer 210 may be removed, and a portion of the bit line capping layer 140 (e.g., the sidewall of the third capping layer 146) may be exposed.

In some example embodiments, the process of removing a portion of the inner spacer 152 may be a wet etching process or a dry etching process. In such an etching process, a portion of the inner spacer 152, which is at a lower level than the upper surface of the protective layer 210, may not be exposed to the etching atmosphere, and a portion of the inner spacer 152, which is at a higher level than the upper surface of the protective layer 210, may only be removed.

After the process of removing a portion of the inner spacer 152, the upper surface of the inner spacer 152 may be placed on the same plane as the upper surface of the protective layer 210 and may have a flat profile.

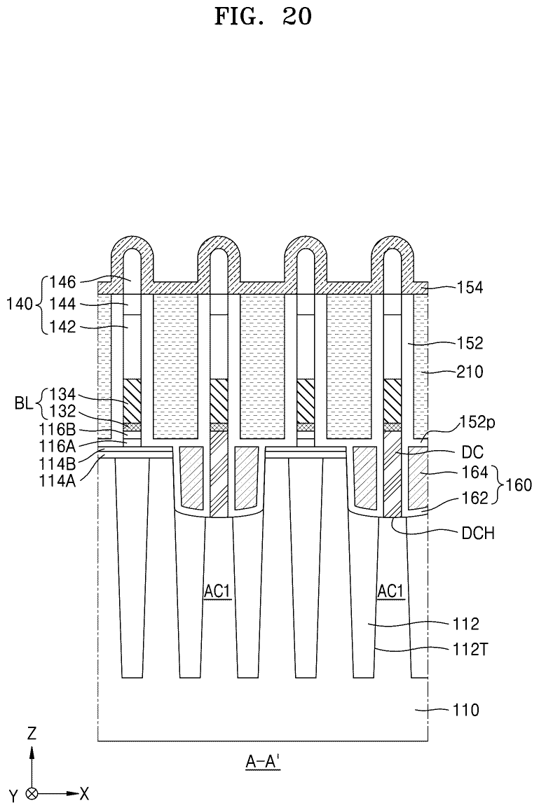

Referring to FIG. 20, the upper capping spacer 154 may be formed on the upper surface of the protective layer 210, the upper surface of the inner spacer 152, and the exposed surface of the third capping layer 146.

In some example embodiments, the upper capping spacer 154 may include a second material, and the second material may be different from the first material forming the inner spacer 152 and may have an etch selectivity with respect to the first material. In some example embodiments, the second material may include at least one of SiN, SiON, SiOC, SiOCN, and/or TiN.

In some example embodiments, the thickness of the upper capping spacer 154 may be the same as that of the inner spacer 152. In some example embodiments, the thickness of the upper capping spacer 154 may be in a range from about 1 nm to about 20 nm.

In other example embodiments, the thickness of the upper capping spacer 154 may be greater than that of the inner spacer 152. In this case, the semiconductor device 100A described above with reference to FIGS. 6 and 7 may be manufactured.

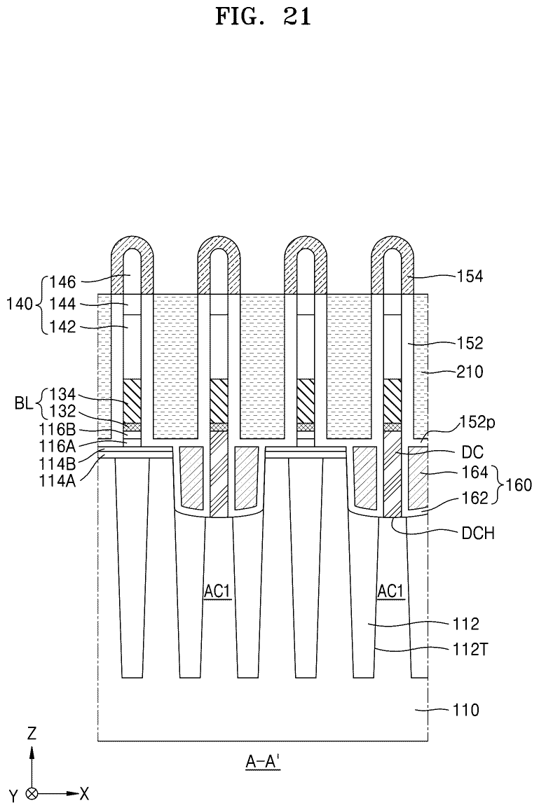

Referring to FIG. 21, through an anisotropic etching process performed on the upper side of the upper capping spacer 154, a portion of the upper capping spacer 154 arranged on the upper surface of the protective layer 210 may be removed, and only a portion of the upper capping spacer 154 arranged on the upper surface and the sidewall of the third capping layer 146 may remain.

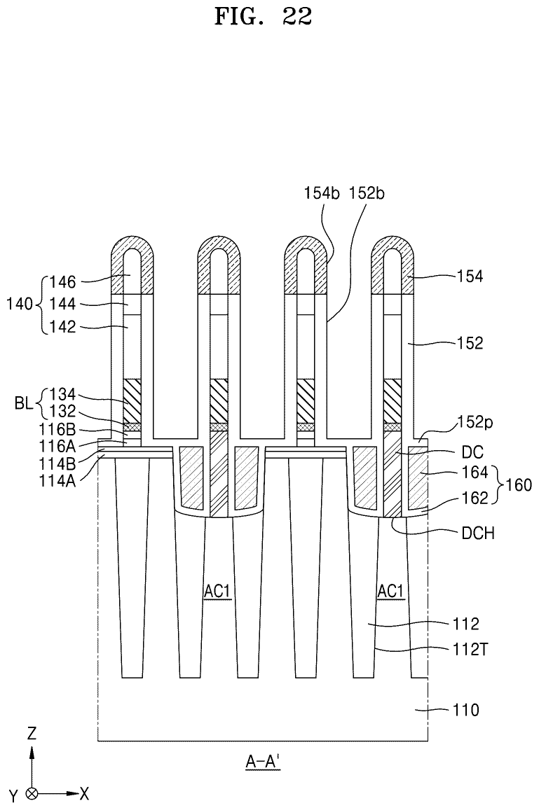

Referring to FIG. 22, the protective layer 210 may be removed.

As the protective layer 210 is removed, the second sidewall 152b of the inner spacer 152 may be exposed.

As illustrated in FIG. 22, the bottom surface of the upper capping spacer 154 may contact the upper surface of the inner spacer 152, and the second sidewall 152b of the inner spacer 152 may be aligned (e.g., coplanar) with or continuously connected to the second sidewall 154b of the upper capping spacer 154.

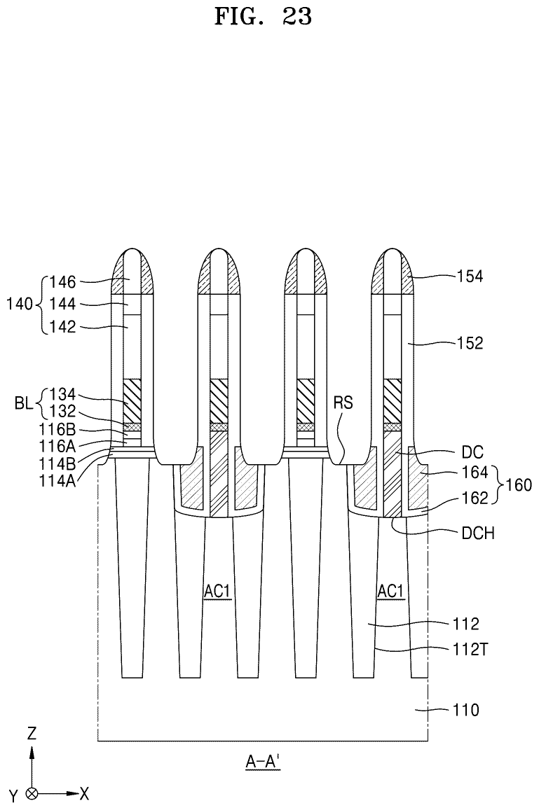

Referring to FIG. 23, the first buffer insulating layer 114A, the second buffer insulating layer 114B, and the horizontal extension 152p of the insulating layer 152 may be removed, and the upper surface of the substrate 110 may be exposed. While the first buffer insulating layer 114A, the second buffer insulating layer 114B, and the horizontal extension 152p of the insulating layer 152 are removed, a portion of the substrate 110 and a portion of the bit line contact spacer 160 are removed together such that a recess RS may be formed.

In some example embodiments, during the etching process for forming the recess RS exposing the upper surface of the substrate 110, an upper side of the upper capping spacer 154 may be partially removed together, and for example, the upper capping spacer 154 may have a shape tapered upwards.

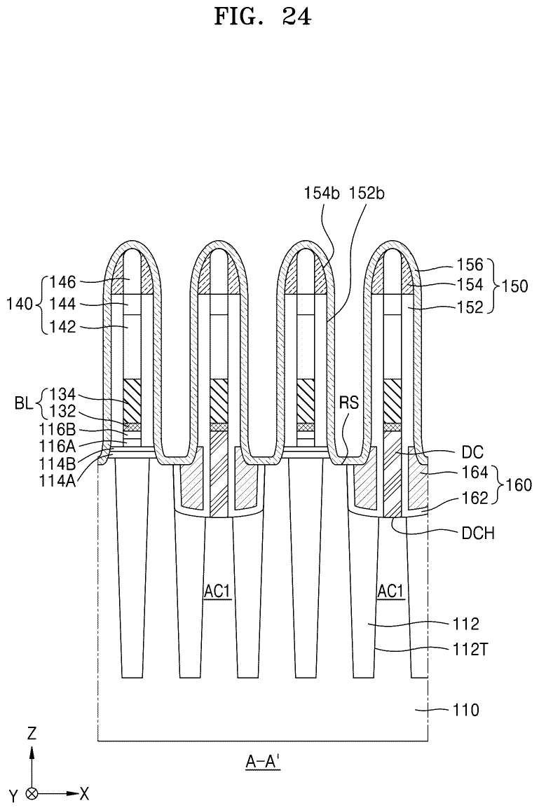

Referring to FIG. 24, the outer spacer 156 may be formed on the second sidewall 152b of the inner spacer 152, the second sidewall 154b of the upper capping spacer 154, and the inner wall of the recess RS.

In some example embodiments, the outer spacer 156 may be conformally formed throughout the total heights of the bit line BL and the bit line capping layer 140 to cover the same. In some example embodiments, the outer spacer 156 may be formed to have a thickness that is less than that of the inner spacer 152.

In some example embodiments, the outer spacer 156 may include SiN.

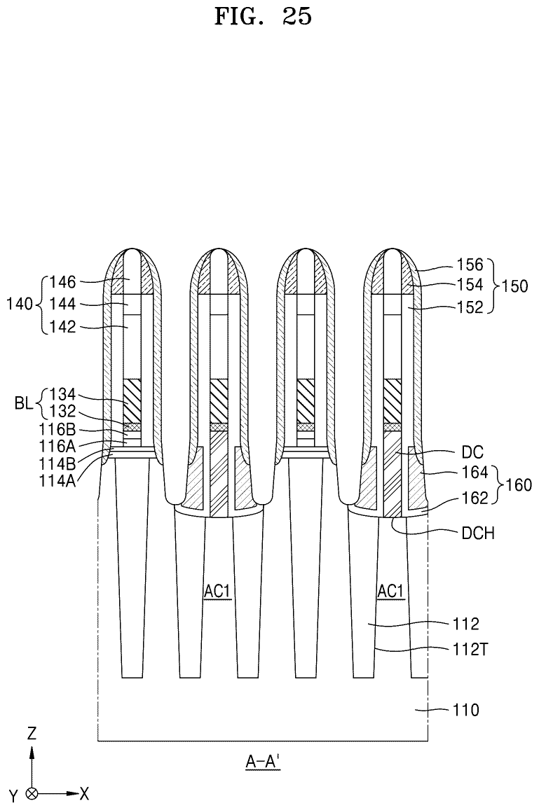

Referring to FIG. 25, the upper surface of the substrate 110 (e.g., the first active area AC1) may be exposed again by performing an anisotropic etching process on the outer spacer 156, and as the exposed upper portion of the substrate 110 is removed, the buried contact hole BCH may be formed, wherein the buried contact hole extends into the substrate 110 by expanding the recess RS downwards.

In some example embodiments, the process of forming the buried contact hole BCH may include the wet etching process, the dry etching process, or a combination thereof. During the etching process for forming the buried contact hole BCH, an upper portion of the outer spacer 156 may be partially removed together such that the outer spacer 156 may be tapered upwards.

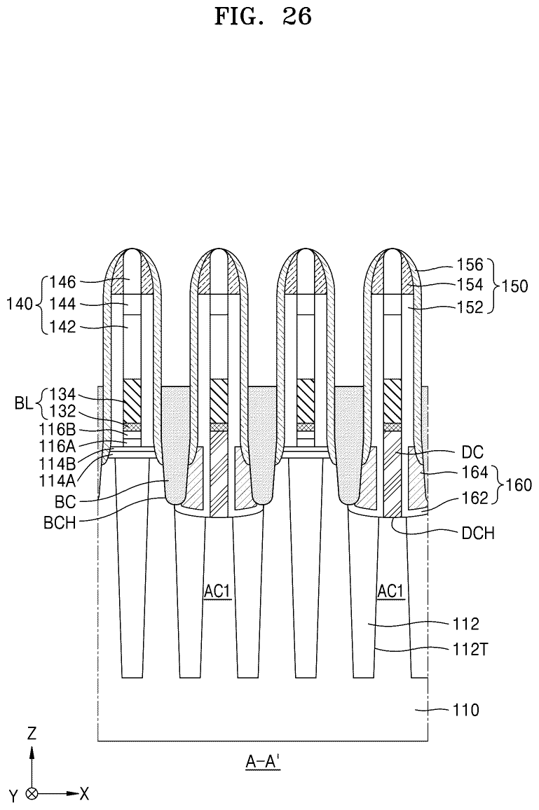

Referring to FIG. 26, the buried contact BC filling the inside of the buried contact hole BCH may be formed. In some example embodiments, the buried contact BC may be formed using doped polysilicon.

In some example embodiments, the buried contact hole BCH may be formed to have a planar shape of a line type that is arranged between adjacent bit lines BL (e.g., between adjacent bit line spacer structures 150), and then, the buried contact BC may be formed by forming a preliminary contact layer having a planar shape of a line type in the buried contact hole BCH and patterning the preliminary contact layer. An insulating fence may be formed using an insulating material in the space between the buried contacts BC (e.g., the space where a portion of the preliminary contact layer is removed).

In other example embodiments, before the buried contact hole BCH is formed, the insulating fences may be formed of insulating materials between two adjacent bit lines BL and at the intersection of the word line trenches 120T, the buried contact hole BCH may be formed by removing a portion of the substrate 110 arranged between the bit lines BL and the insulating fences, and then the buried contact BC may be formed in the buried contact hole BCH.

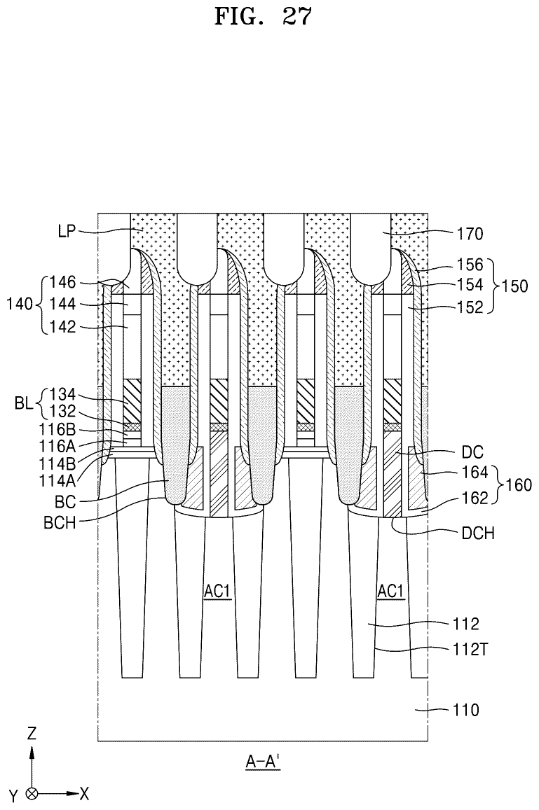

Referring to FIG. 27, the conductive layer may be formed on the upper surfaces of the buried contacts BC, and the landing pads LP may be formed by patterning the conductive layer. Then, the insulating pattern 170 surrounding the landing pad LP may be formed. The insulating pattern 170 may be arranged to cover the sidewalls of the landing pads LP.

Referring back to FIGS. 3 and 4, the lower electrodes 182 connected to the landing pads LP may be formed, and the capacitor dielectric layer 184 and the upper electrode 186 may be sequentially formed on the sidewalls of the lower electrodes 182.

The semiconductor device 100 may be completely manufactured by performing the above processes.

According to some example embodiments, the upper capping spacer 154 may be formed using a material with an etch selectivity with respect to the inner spacer 152, and thus, the upper capping spacer 154 may function as a mask during the etching process for forming the buried contact hole BCH or the process of forming the buried contact BC, thus preventing or reducing in likelihood the exposure or damage to the inner spacer 152. Therefore, the semiconductor device 100 may have reduced parasitic capacitance, and thus, the electrical characteristics of the semiconductor device 100 may be improved.

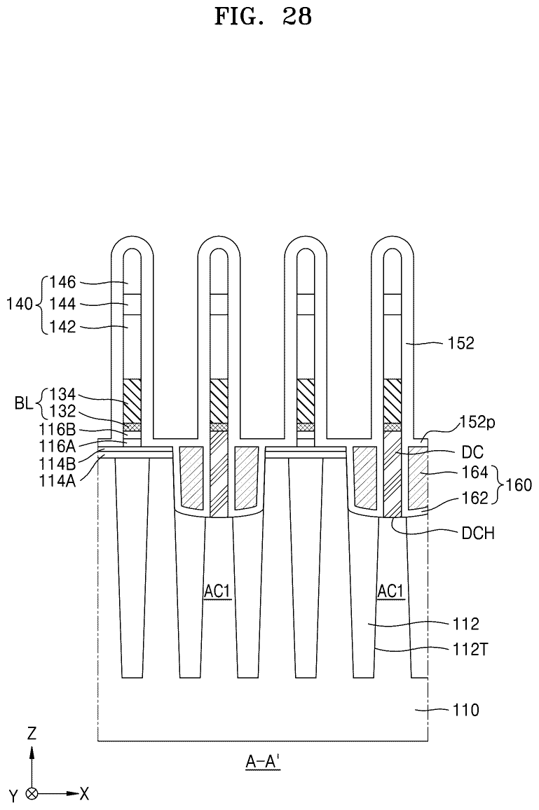

FIGS. 28 to 37 are cross-sectional views showing a method of manufacturing the semiconductor device 100A, according to some example embodiments. In detail, FIGS. 28 to 37 are cross-sectional views corresponding to the cross-section A-A′ of FIG. 2.

Referring to FIG. 28, the inner spacer 152 may be formed on the bit line BL and the sidewall of the bit line capping layer 140 by performing the processes described with reference to FIGS. 12A to 15.

The inner spacer 152 may be conformally arranged on the bit line BL and the sidewall of the bit line capping layer 140, and the horizontal extension 152p of the inner spacer 152 may cover the upper surface of the bit line contact spacer 160.

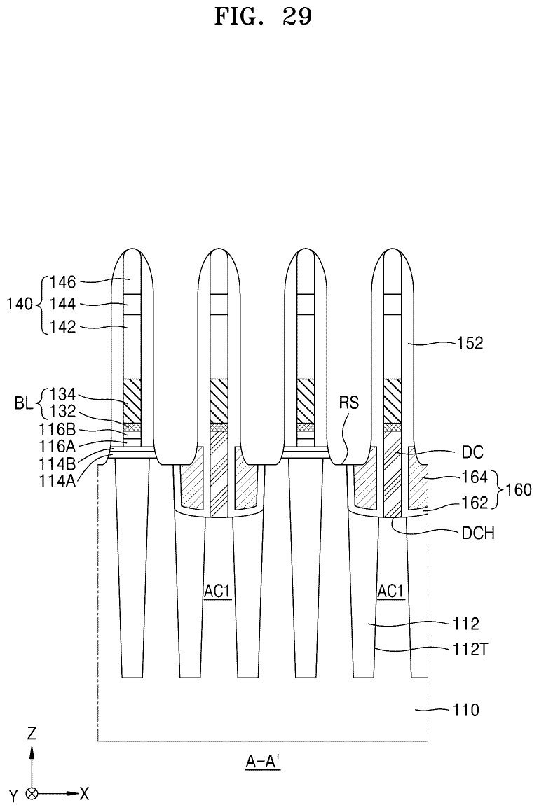

Referring to FIG. 29, the first buffer insulating layer 114A, the second buffer insulating layer 114B, and the horizontal extension 152p of the inner spacer 152 may be removed, and the upper surface of the substrate 110 may be exposed. While the first buffer insulating layer 114A, the second buffer insulating layer 114B, and the horizontal extension 152p of the inner spacer 152 are removed, a portion of the substrate 110 and a portion of the bit line contact spacer 160 are removed together such that the recess RS may be formed.

In some example embodiments, during the etching process for forming the recess RS exposing the upper surface of the substrate 110, the upper side of the inner spacer 152 may be partially removed together, and for example, the inner spacer 152 may be tapered upwards.

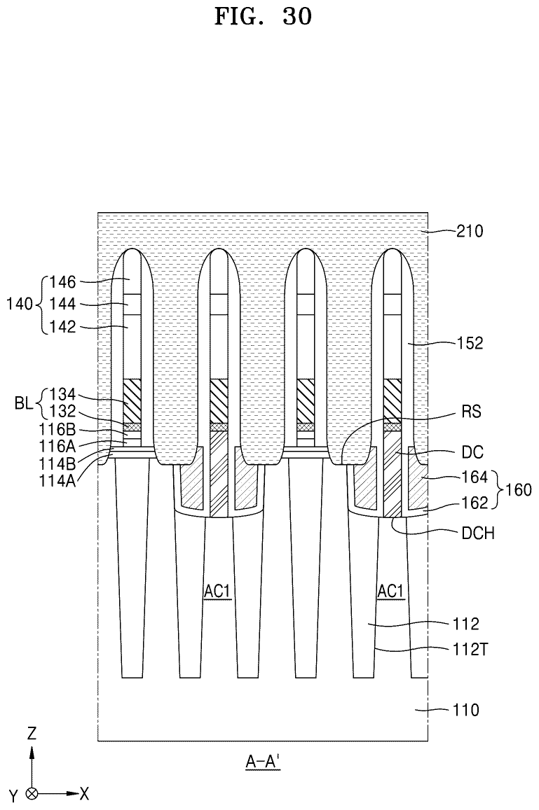

Referring to FIG. 30, the protective layer 210 may be formed on the inner spacer 152. The protective layer 210 may be formed at a height that is sufficient to cover the uppermost surface of the inner spacer 152, and the space between adjacent bit lines BL, for example, the interior of the recess RS, may be fully filled with the protective layer 210.

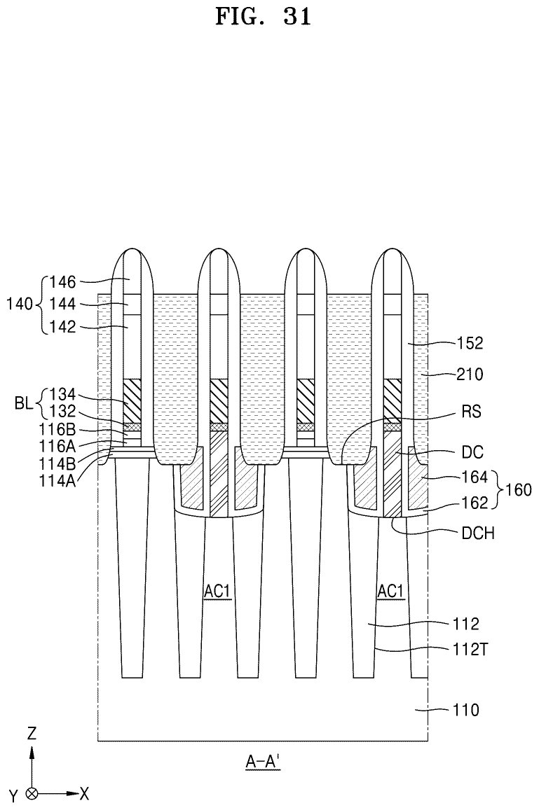

Referring to FIG. 31, the height of the protective layer 210 may be reduced by performing the etch-back process on the upper side of the protective layer 210. Consequently, the upper side of the inner spacer 152 may be exposed.

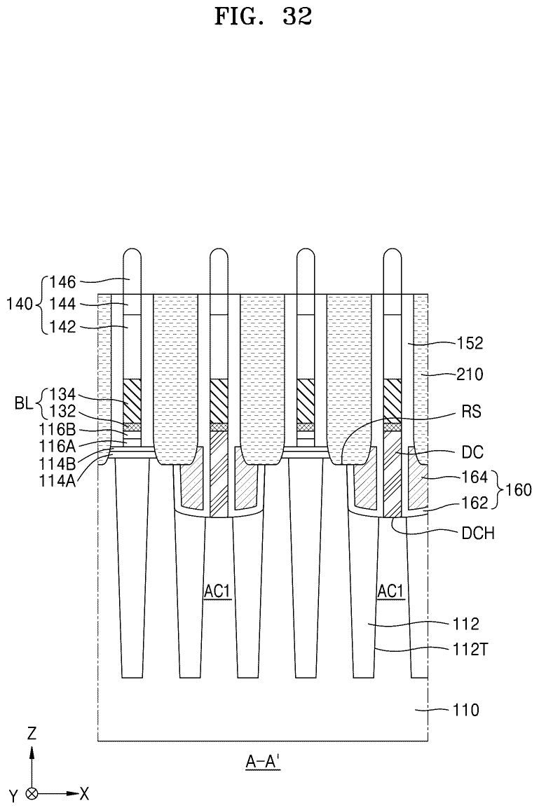

Referring to FIG. 32, a portion of the inner spacer 152 exposed above the upper surface of the protective layer 210 may be removed, and a portion of the bit line capping layer 140 (e.g., the sidewall of the third capping layer 146) may be exposed.

In some example embodiments, the process of removing a portion of the inner spacer 152 may be a wet etching process or a dry etching process. After the process of removing a portion of the inner spacer 152, the upper surface of the inner spacer 152 may be placed on the same plane as the upper surface of the protective layer 210 and may have a flat profile.

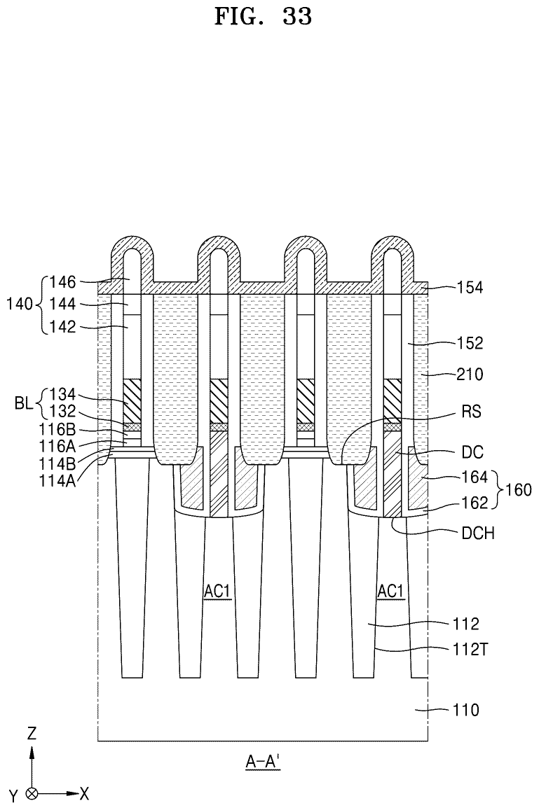

Referring to FIG. 33, the upper capping spacer 154 may be formed on the upper surface of the protective layer 210, the upper surface of the inner spacer 152, and the exposed surface of the third capping layer 146.

In some example embodiments, the upper capping spacer 154 may include a second material, and the second material may be different from the first material forming the inner spacer 152 and may have an etch selectivity with respect to the first material. In some example embodiments, the second material may include at least one of SiN, SiON, SiOC, SiOCN, and/or TiN.

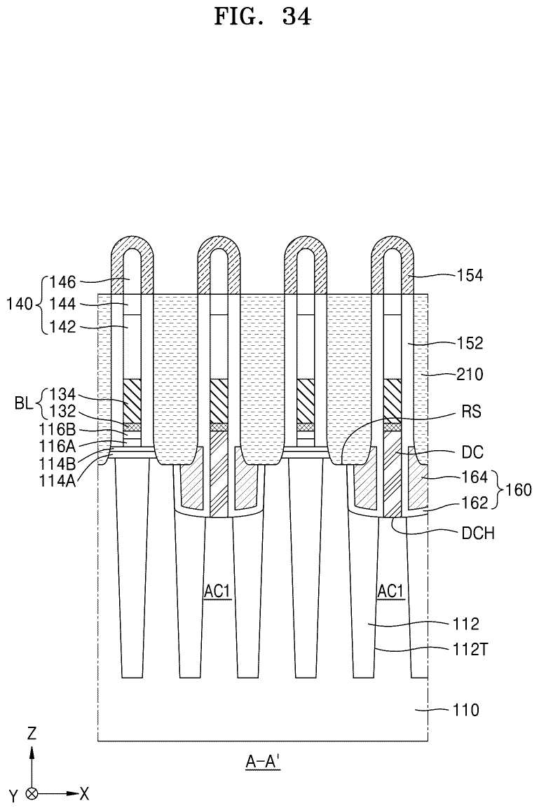

Referring to FIG. 34, through the anisotropic etching process performed on the upper side of the upper capping spacer 154, a portion of the upper capping spacer 154 arranged on the upper surface of the protective layer 210 may be removed, and only a portion of the upper capping spacer 154 arranged on the upper surface and the sidewall of the third capping layer 146 may remain.

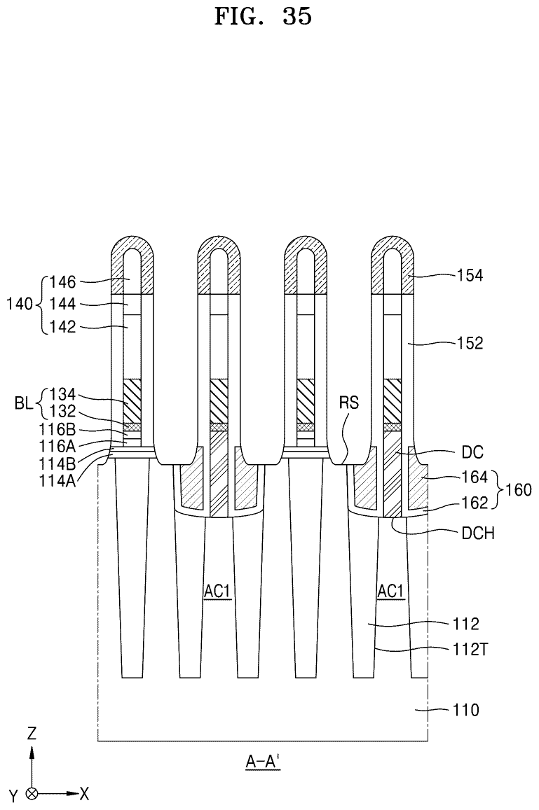

Referring to FIG. 35, the protective layer 210 may be removed.

Due to the removal of the protective layer 210, the second sidewall 152b of the inner spacer 152 may be exposed, and the inner wall of the recess RS, for example, the upper surface of the substrate 110 and the upper surface of the bit line contact spacer 160 on the inner wall of the recess RS, may be exposed.

The upper capping spacer 154 may cover the uppermost surface of the third capping layer 146, and the thickness of the upper capping spacer 154 on the uppermost surface of the third capping layer 146 may be the same as or similar to the thickness of the bottom surface of the upper capping spacer 154 on the upper surface of the inner spacer 152.

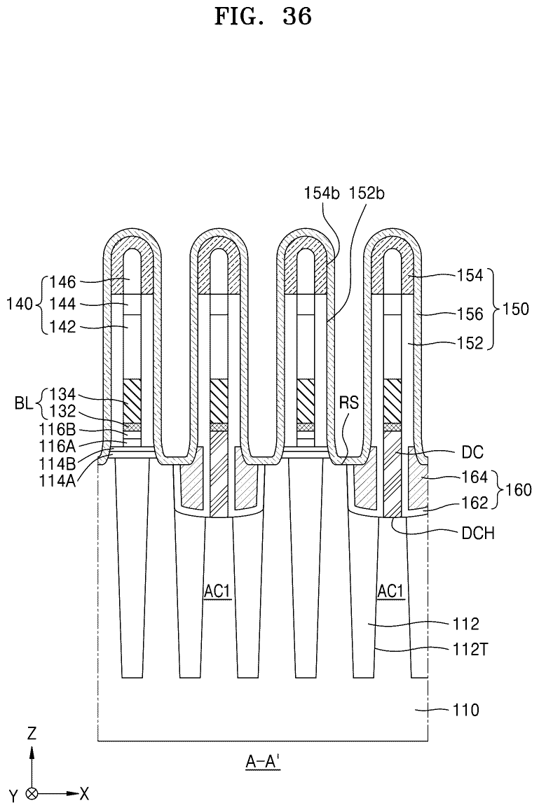

Referring to FIG. 36, the outer spacer 156 may be formed on the second sidewall 152b of the inner spacer 152, the second sidewall 154b of the upper capping spacer 154, and the inner wall of the recess RS.

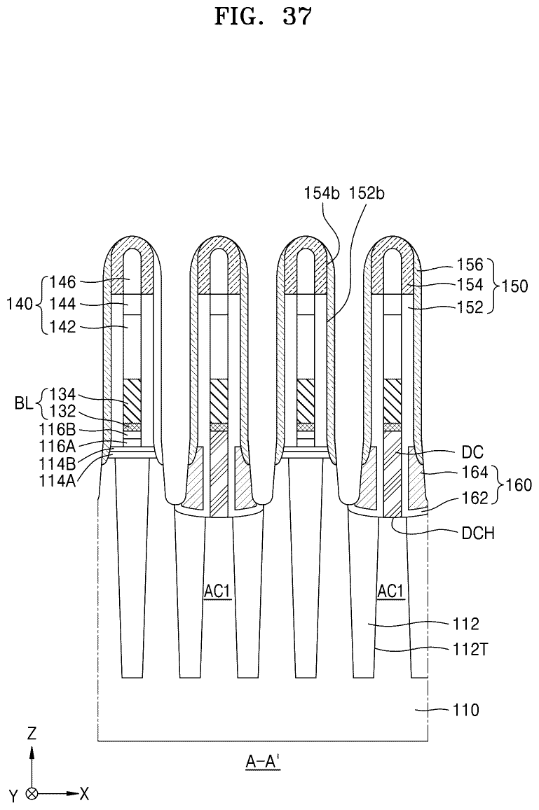

Referring to FIG. 37, the upper surface of the substrate 110 (e.g., the first active area AC1) may be exposed again by performing an anisotropic etching process on the outer spacer 156, and as the exposed upper portion of the substrate 110 is removed, the buried contact hole BCH may be formed, wherein the buried contact hole extends into the substrate 110 by expanding the recess RS downwards.

Then, the semiconductor device 100A may be completed by performing the processes described with reference to FIGS. 26 to 28.

According to one or more example embodiments, an inner spacer including SiO may be formed on both sidewalls of a bit line, and an upper capping spacer including SiN may be formed on the upper surface of the inner spacer and both sidewalls of a bit line capping layer, thus preventing or reducing in likelihood exposure to the etching environment or damage to the inner spacer during the etching process for forming a buried contact hole. A semiconductor device may have reduced parasitic capacitance, and thus, the electrical characteristics of the semiconductor device may be improved.

While the inventive concepts have been particularly shown and described with reference to example embodiments thereof, it will be understood that various changes in form and details may be made therein without departing from the spirit and scope of the following claims.

What is claimed is:

1. A semiconductor device comprising:
a substrate including a first active area;
a bit line on the substrate, the bit line crossing the first active area and extending in a first direction parallel to an upper surface of the substrate;
a bit line capping layer extending in the first direction, the bit line capping layer on an upper surface of the bit line; and
a spacer structure on a sidewall of the bit line and a sidewall of the bit line capping layer, wherein the spacer structure includes,
an inner spacer on the sidewall of the bit line and a lower side of the sidewall of the bit line capping layer;
an upper capping spacer on an upper side of the sidewall of the bit line capping layer; and
an outer spacer on a sidewall of the inner spacer and a sidewall of the upper capping spacer.

2. The semiconductor device of claim 1, wherein a bottom surface of the upper capping spacer is on an upper surface of the inner spacer.

3. The semiconductor device of claim 1, wherein the upper capping spacer vertically overlaps the inner spacer.

4. The semiconductor device of claim 1, wherein a bottom surface of the upper capping spacer is at a higher level than the upper surface of the bit line.

5. The semiconductor device of claim 1, wherein
an upper surface of the inner spacer has a flat profile, and
a bottom surface of the upper capping spacer has a flat profile.

6. The semiconductor device of claim 1, wherein
the inner spacer includes silicon oxide (SiO), and
the upper capping spacer includes silicon nitride (SiN), silicon oxynitride (SiON), silicon oxycarbide (SiOC), silicon oxycarbonitride (SiOCN), or titanium nitride (TiN).

7. The semiconductor device of claim 1, wherein
the inner spacer has a first width in a second direction that is parallel to the substrate and crosses the first direction, and
the upper capping spacer has a second width in the second direction, the second width being a same as the first width.

8. The semiconductor device of claim 7, wherein
the inner spacer includes a first sidewall facing the sidewall of the bit line and a second sidewall opposite to the first sidewall,
the upper capping spacer includes a first sidewall facing the sidewall of the bit line capping layer and a second sidewall opposite to the first sidewall, and
the second sidewall of the upper capping spacer is aligned with the second sidewall of the inner spacer.

9. The semiconductor device of claim 8, wherein
the outer spacer is on the second sidewall of the inner spacer and the second sidewall of the upper capping spacer,
the outer spacer has a third width in the second direction, and
the third width is less than the first width.

10. The semiconductor device of claim 1, wherein
the inner spacer has a first width in a second direction that is parallel to the substrate and crosses the first direction,
the upper capping spacer has a second width in the second direction, and
the second width is greater than the first width.

11. The semiconductor device of claim 10, wherein
the inner spacer includes a first sidewall facing the sidewall of the bit line and a second sidewall opposite to the first sidewall,
the upper capping spacer a first sidewall facing the sidewall of the bit line capping layer and a second sidewall opposite to the first sidewall, and
the second sidewall of the upper capping spacer protrudes outwards with respect to the second sidewall of the inner spacer.

12. The semiconductor device of claim 1, further comprising:
a bit line contact between the bit line and the first active area and in a bit line contact hole defined by the substrate;
a bit line contact spacer in the bit line contact hole and on a sidewall of the bit line contact; and
a buried contact in a buried contact hole extending into the substrate, wherein at least a portion of a lower side of a sidewall of the buried contact is in contact with the bit line contact spacer and at least a portion of an upper side of the sidewall of the buried contact is in contact with the outer spacer.

13. The semiconductor device of claim 12, further comprising:
a liner between the spacer structure and the sidewall of the bit line capping layer and on the spacer structure and the sidewall of the bit line,
wherein the liner extends to the upper surface of the bit line contact spacer.

14. A semiconductor device comprising:
a substrate including a first active area;
a bit line on the substrate, the bit line crossing the first active area and extending in a first direction parallel to an upper surface of the substrate;
a bit line capping layer extending in the first direction, the bit line capping layer on an upper surface of the bit line; and
a spacer structure on a sidewall of the bit line and a sidewall of the bit line capping layer, wherein the spacer structure includes,
an inner spacer on the sidewall of the bit line and a lower side of the sidewall of the bit line capping layer and including a first material;
an upper capping spacer on an upper side of the sidewall of the bit line capping layer and including a second material that is different from the first material; and
an outer spacer on a sidewall of the inner spacer and a sidewall of the upper capping spacer,
wherein a bottom surface of the upper capping spacer is at a higher vertical level than the upper surface of the bit line.

15. The semiconductor device of claim 14, wherein
the first material includes silicon oxide (SiO), and
the second material includes silicon nitride (SiN), silicon oxynitride (SiON), silicon oxycarbide (SiOC), silicon oxycarbonitride (SiOCN), or titanium nitride (TiN).

16. The semiconductor device of claim 14, further comprising:
a bit line contact between the bit line and the first active area and in a bit line contact hole extending into the substrate;
a bit line contact spacer in the bit line contact hole and on a sidewall of the bit line contact; and
a buried contact in a buried contact hole extending into the substrate,
wherein at least a portion of a lower side of a sidewall of the buried contact is in contact with the bit line contact spacer and at least a portion of an upper side of the sidewall of the buried contact is in contact with the outer spacer.

17. The semiconductor device of claim 14, wherein
the bottom surface of the upper capping spacer is on an upper surface of the inner spacer,
the upper surface of the inner spacer has a flat profile, and
the bottom surface of the upper capping spacer has a flat profile.

18. The semiconductor device of claim 14, wherein the upper capping spacer vertically overlaps the inner spacer.

19. A semiconductor device comprising:
a substrate comprising a plurality of first active areas;
a plurality of bit lines on the substrate, the plurality of bit lines crossing the plurality of first active areas and extending in a first direction parallel to an upper surface of the substrate;
a plurality of bit line capping layers respectively extending in the first direction, the plurality of bit line capping layers on upper surfaces of the plurality of bit lines;
a bit line contact between the plurality of first active areas, the bit line contact corresponding to a first bit line among the plurality of bit lines and in a bit line contact hole extending into the substrate;
a bit line contact spacer filling an inside of the bit line contact hole and contacting a sidewall of the bit line contact;
a buried contact between the first bit line and a second bit line, the buried contact is adjacent to the first bit line among the plurality of bit lines and in a buried contact hole extending into the substrate;
a spacer structure on a sidewall of the first bit line, wherein the spacer structure includes,
an inner spacer comprising a first material and on the sidewall of the first bit line and a lower side of a sidewall of a first bit line capping layer on an upper surface of the first bit line;
an upper capping spacer on an upper side of the sidewall of the first bit line capping layer and including a second material different from the first material; and
an outer spacer on a sidewall of the inner spacer and a sidewall of the upper capping spacer,
wherein the semiconductor device further includes a landing pad on the buried contact, and
the outer spacer is in contact with a sidewall of the buried contact and a sidewall of the landing pad.

20. The semiconductor device of claim 19, wherein a sidewall of the inner spacer is covered by the outer spacer, and the inner spacer is not in contact with the landing pad.
